(19) United States
(12) Patent Application Publication
(10) Pub. No.: US 2023/0395698 A1
(43) Pub. Date: Dec. 7, 2023

(54) SEMICONDUCTOR STRUCTURE AND MANUFACTURING METHOD THEREOF

(71) Applicant: Powerchip Semiconductor Manufacturing Corporation, Hsinchu (TW)

(72) Inventors: Tien-Lu Lin, Hsinchu City (TW); Ying-Chia Lin, Hsinchu City (TW); Chuen-Jiunn Shyu, Hsinchu City (TW); Shou-Zen Chang, Hsinchu City (TW)

(73) Assignee: Powerchip Semiconductor Manufacturing Corporation, Hsinchu (TW)

(21) Appl. No.: 17/849,757

(22) Filed: Jun. 27, 2022

(30) Foreign Application Priority Data
Jun. 2, 2022 (TW) 111120641

(51) Int. Cl. H01L 29/66; H01L 29/49; H01L 21/28

(52) U.S. Cl. CPC H01L 29/66545; H01L 21/28132; H01L 21/28088; H01L 29/4975

(57) ABSTRACT

Disclosed are a semiconductor structure and a manufacturing method thereof. The semiconductor structure includes a substrate, a first dielectric layer, a first gate, a second dielectric layer, and a second gate. The first dielectric layer is located on the substrate. The first gate is located on the first dielectric layer. The second dielectric layer is located on the substrate. The second gate is located on the second dielectric layer. A bottom surface of the second gate and a bottom surface of the first gate are located on different planes.

### CROSS-REFERENCE TO RELATED APPLICATION

This application claims the priority benefit of Taiwanese application no. 111120641, filed on Jun. 2, 2022. The entirety of the above-mentioned patent application is hereby incorporated by reference herein and made a part of this specification.

### BACKGROUND

### Technical Field

The disclosure relates to a semiconductor structure and a manufacturing method thereof. Particularly, the disclosure relates to a semiconductor structure with a relatively low on-resistance (Rₒₙ) and a manufacturing method thereof.

### Description of Related Art

In some semiconductor structures (e.g., a transistor structure), electrical performance of the semiconductor structure may be improved by reducing an on-resistance of the semiconductor structure. Therefore, how to reduce the on-resistance of the semiconductor structure is currently an aim to continuously put efforts in.

### SUMMARY

The disclosure provides a semiconductor structure and a manufacturing method thereof, in which an on-resistance of the semiconductor structure is reduced.

According to an embodiment of the disclosure, a semiconductor structure includes a substrate, a first dielectric layer, a first gate, a second dielectric layer, and a second gate. The first dielectric layer is located on the substrate. The first gate is located on the first dielectric layer. The second dielectric layer is located on the substrate. The second gate is located on the second dielectric layer. A bottom surface of the second gate and a bottom surface of the first gate are located on different planes.

According to an embodiment of the disclosure, in the semiconductor structure, the bottom surface of the second gate may be higher than the bottom surface of the first gate.

According to an embodiment of the disclosure, in the semiconductor structure, the second dielectric layer and the first dielectric layer may be separated from each other.

According to an embodiment of the disclosure, in the semiconductor structure, the second dielectric layer may have a recess, and the second gate may be located in the recess.

According to an embodiment of the disclosure, the semiconductor structure may further include a conductive spacer located on a sidewall of the recess.

According to an embodiment of the disclosure, in the semiconductor structure, the conductive spacer and the second gate may be separated from each other.

According to an embodiment of the disclosure, in the semiconductor structure, the second dielectric layer may be further located on the first gate.

According to an embodiment of the disclosure, the semiconductor structure may further include a hard mask layer. The hard mask layer is located on the second gate.

According to an embodiment of the disclosure, in the semiconductor structure, a width of the hard mask layer may be equal to a width of the second gate.

According to an embodiment of the disclosure, the semiconductor structure may further include a stop layer. The stop layer is located on the first gate.

According to an embodiment of the disclosure, in the semiconductor structure, the stop layer may be in direct contact with a top surface of the first gate.

According to an embodiment of the disclosure, in the semiconductor structure, the stop layer may be located between the second dielectric layer and the first gate.

According to an embodiment of the disclosure, in the semiconductor structure, the stop layer may be not located directly below the second gate.

According to an embodiment of the disclosure, a manufacturing method of a semiconductor structure includes the following. A substrate is provided. A first dielectric layer is formed on the substrate. A first gate is formed on the first dielectric layer. A second dielectric layer is formed on the substrate. A second gate is formed on the second dielectric layer. A bottom surface of the second gate and a bottom surface of the first gate are located on different planes.

According to an embodiment of the disclosure, in the manufacturing method, the bottom surface of the second gate may be higher than the bottom surface of the first gate.

According to an embodiment of the disclosure, in the manufacturing method, forming the second gate may include the following. A conductive material layer is formed on the second dielectric layer. A hard mask material layer is formed on the conductive material layer. The hard mask material layer and the conductive material layer are patterned to form a hard mask layer and the second gate.

According to an embodiment of the disclosure, in the manufacturing method, the second dielectric layer may have a recess, and the hard mask layer and the second gate may be located in the recess.

According to an embodiment of the disclosure, in the manufacturing method, patterning the conductive material layer may further form a conductive spacer on a sidewall of the recess.

According to an embodiment of the disclosure, the manufacturing method may further include the following. A stop layer is formed on the first gate before the second dielectric layer is formed. A third dielectric layer is formed on the stop layer. An opening is formed in the third dielectric layer and the stop layer. The second dielectric layer may further be formed on the third dielectric layer and in the opening.

According to an embodiment of the disclosure, the manufacturing method may further include the following. A planarization process is performed on the third dielectric layer before the opening is formed.

Based on the foregoing, in the semiconductor structure and the manufacturing method thereof according to the embodiments of the disclosure, since the semiconductor structure includes the first gate and the second gate, and the bottom surface of the second gate and the bottom surface of the first gate are located on different planes, the on-resistance of the semiconductor structure may be reduced by the second gate, accordingly improving the electrical performance of the semiconductor structure.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1E are cross-sectional views of process flows of manufacturing a semiconductor structure according to some embodiments of the disclosure.

### DESCRIPTION OF THE EMBODIMENTS

Embodiments with accompanying drawings are described in detail below, but the embodiments described are not intended to limit the coverage scope of the disclosure. For ease of understanding, the same members will be described with the same reference numerals in the following description. In addition, the drawings only serve for illustration, and are not drawn in original scale. In fact, dimensions of various features may be arbitrarily increased or decreased for clarity of description.

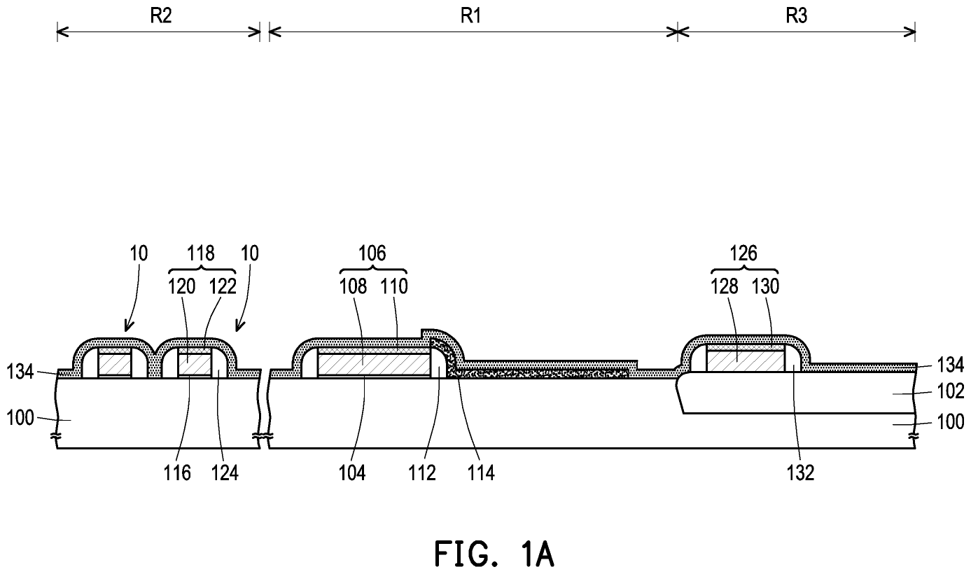

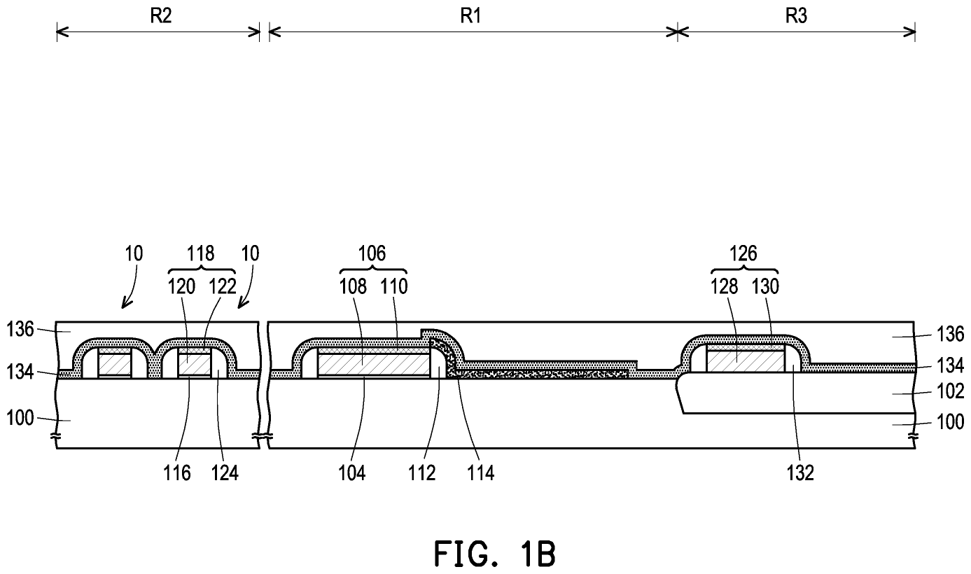

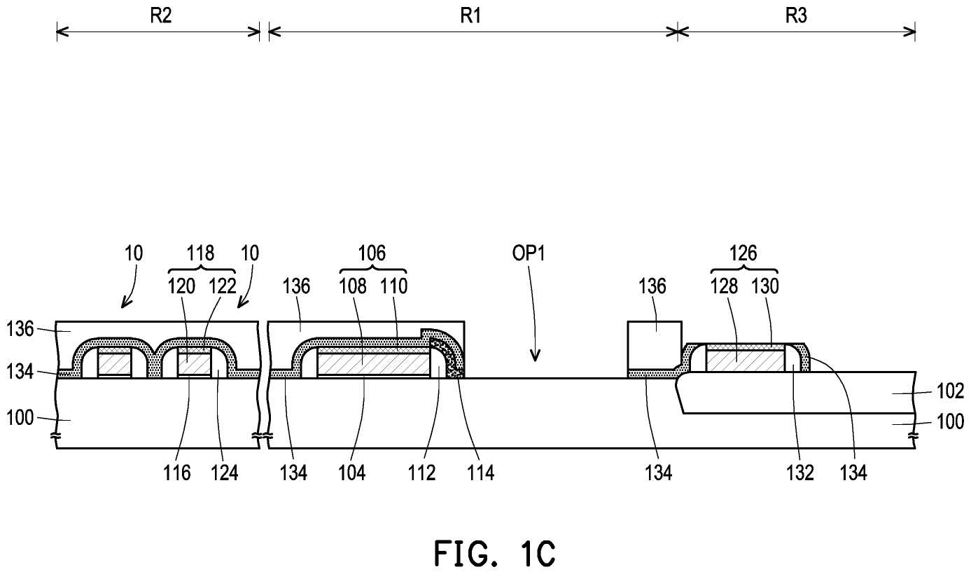

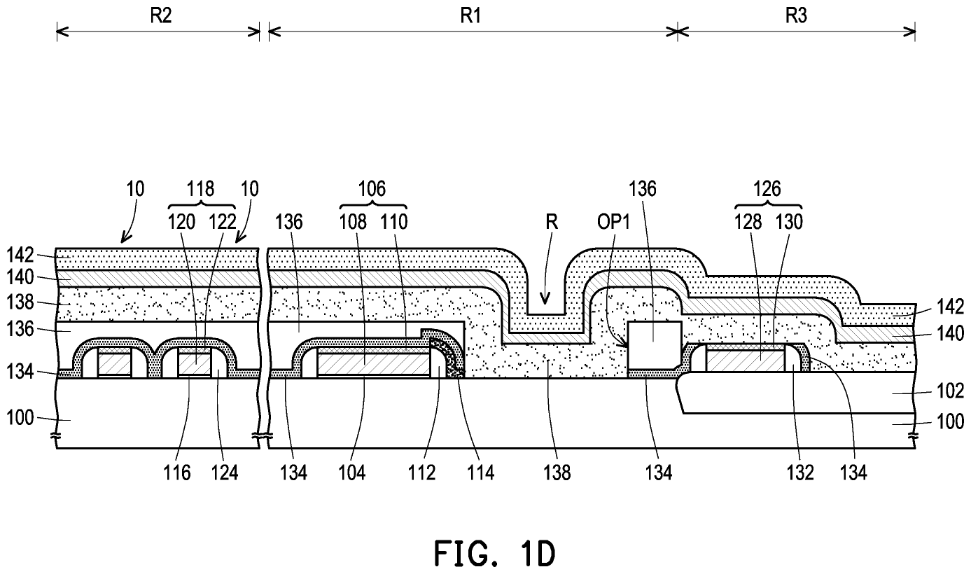

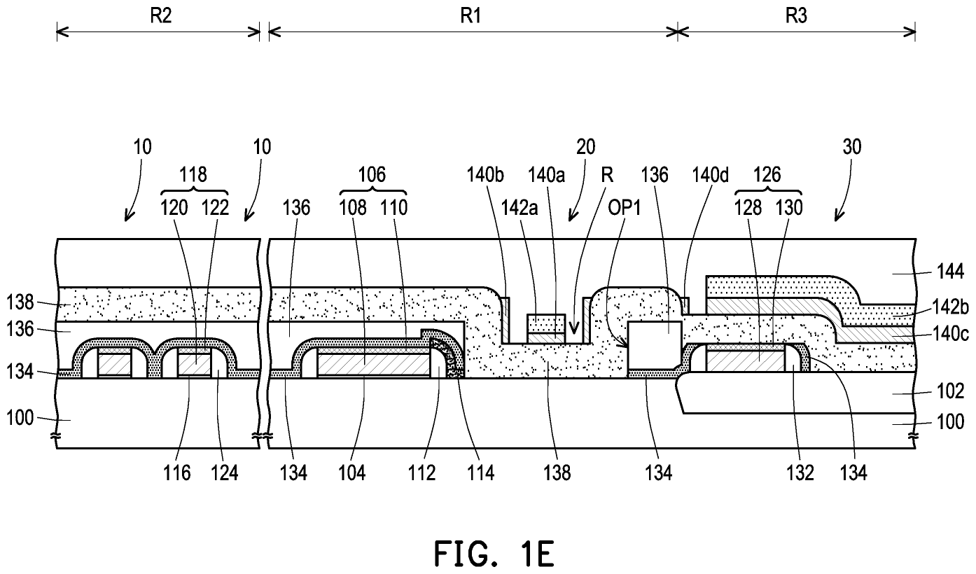

FIG. 1A to FIG. 1E are cross-sectional views of process flows of manufacturing a semiconductor structure according to some embodiments of the disclosure.

With reference to FIG. 1A, a substrate 100 is provided. The substrate 100 may include a first region R1. In some embodiments, the first region R1 may be a high voltage element region. In some embodiments, the substrate 100 may further include at least one of a second region R2 and a third region R3. In some embodiments, the second region R2 may be a low voltage element region. In some embodiments, the third region R3 may be a capacitor region. The substrate 100 may be a semiconductor substrate, for example, a silicon substrate. In addition, the substrate 100 may include an isolation structure 102 therein. The isolation structure 102 is a shallow trench isolation (STI), for example. The material of the isolation structure 102 may be silicon oxide, for example. Moreover, the substrate 100 may include a doped region (not shown) therein depending on requirements, and the doped region may include a metal silicide (not shown) thereon, of which the description is omitted here.

In addition, a dielectric layer 104 is formed on the substrate 100. The dielectric layer 104 may be located in the first region R1. The material of the dielectric layer 104 is silicon oxide, for example. Moreover, a gate 106 is formed on the dielectric layer 104. The gate 106 may be a single-layer structure or a multi-layer structure. In this embodiment, the gate 106 is described using a multi-layer structure as an example. For example, the gate 106 may include a conductive layer 108 and a metal silicide layer 110, but the disclosure is not limited thereto. The conductive layer 108 is located on the dielectric layer 104. The material of the conductive layer 108 is doped polysilicon, for example. The metal silicide layer 110 is located on the conductive layer 108. The material of the metal silicide layer 110 is cobalt silicide (CoSi) or nickel silicide (NiSi), for example.

In some embodiments, a spacer 112 may be formed on a sidewall of the gate 106. The spacer 112 may be a single-layer structure or a multi-layer structure. The material of the spacer 112 is silicon oxide, silicon nitride (SiN), or a combination thereof, for example. In some embodiments, a salicide blocking (SAB) layer 114 may be formed on part of the substrate 100. In addition, the salicide blocking layer 114 may be located on the spacer 112. The salicide blocking layer 114 may have a single-layer structure or a multi-layer structure. The material of the salicide blocking layer 114 is silicon oxide, silicon nitride, silicon oxynitride (SiON), or a combination thereof, for example.

In some embodiments, a semiconductor structure 10 may be formed on the substrate 100. The semiconductor structure 10 may be located in the second region R2. The semiconductor structure 10 includes at least one semiconductor structure. In this embodiment, the semiconductor structure 10 is described using a plurality of semiconductor structures as an example, and is not limited to the number shown in the figure. In this embodiment, the semiconductor structure 10 may be a transistor structure, for example, a low voltage transistor structure. For example, the plurality of semiconductor structures 10 may be N-type metal oxide semiconductor (NMOS) transistor structures or P-type metal oxide semiconductor (PMOS) transistor structures.

The semiconductor structure 10 may include a dielectric layer 116 and a gate 118. The dielectric layer 116 is located on the substrate 100. The material of the dielectric layer 116 is silicon oxide, for example. The gate 118 is located on the dielectric layer 116. The gate 118 may be a single-layer structure or a multi-layer structure. In this embodiment, the gate 118 is described using a multi-layer structure as an example. For example, the gate 118 may include a conductive layer 120 and a metal silicide layer 122, but the disclosure is not limited thereto. The conductive layer 120 is located on the dielectric layer 116. The material of the conductive layer 120 is doped polysilicon, for example. The metal silicide layer 122 is located on the conductive layer 120. The material of the metal silicide layer 122 is cobalt silicide or nickel silicide, for example.

In some embodiments, the semiconductor structure 10 may further include a spacer 124. The spacer 124 is located on a sidewall of the gate 118. The spacer 124 may be a single-layer structure or a multi-layer structure. The material of the spacer 124 is silicon oxide, silicon nitride, or a combination thereof, for example.

In some embodiments, an electrode 126 may be formed on the isolation structure 102. The electrode 126 may be located in the third region R3. The electrode 126 may be a single-layer structure or a multi-layer structure. In this embodiment, the electrode 126 is described using a multi-layer structure as an example. For example, the electrode 126 may include a conductive layer 128 and a metal silicide layer 130, but the disclosure is not limited thereto. The conductive layer 128 is located on the isolation structure 102. The material of the conductive layer 128 is doped polysilicon, for example. The metal silicide layer 130 is located on the conductive layer 128. The material of the metal silicide layer 130 is cobalt silicide or nickel silicide, for example.

In some embodiments, a spacer 132 may be formed on a sidewall of the electrode 126. The spacer 132 may be a single-layer structure or a multi-layer structure. The material of the spacer 132 is silicon oxide, silicon nitride, or a combination thereof, for example.

Next, a stop layer 134 may be formed on the gate 106. The stop layer 134 may be a contact etch stop layer (CESL). The stop layer 134 may be in direct contact with a top surface of the gate 106. In other words, no other film layer is present between the stop layer 134 and the top surface of the gate 106, which facilitates smoothly forming a contact electrically connected to the gate 106 during the subsequent interconnect manufacturing process, and improves the process window. In addition, the stop layer 134 may further be located on the spacer 112, the salicide blocking layer 114, the gate 118, the spacer 124, the electrode 126, the spacer 132, and part of the substrate 100. In some embodiments, the stop layer 134 may be in direct contact with a top surface of the gate 118. In other words, no other film layer is present between the stop layer 134 and the top surface of the gate 118, which facilitates smoothly forming a contact electrically connected to the gate 118 during the subsequent interconnect manufacturing process, and improves the process window. In some embodiments, the stop layer 134 may be in direct contact with part of a top surface of the substrate 100. In other words, no other film layer is present between the stop layer 134 and part of the top surface of the substrate 100, which facilitates smoothly forming a contact electrically connected to the doped regions (e.g., a source region and/or a drain region) (not shown) in the substrate 100 during the subsequent interconnect manufacturing process, and improves the process window. The material of the stop layer 134 is silicon nitride, silicon oxynitride, silicon carbonitride (SiCN), or silicon oxycarbonitride (SiOCN), for example.

With reference to FIG. 1B, a dielectric layer 136 may be formed on the stop layer 134. The material of the dielectric layer 136 is silicon oxide, for example. The dielectric layer 136 is formed by chemical vapor deposition, for example. Next, a planarization process may be performed on the dielectric layer 136. The planarization process is a chemical mechanical polishing (CMP) process, for example.

With reference to FIG. 1C, an opening OP1 may be formed in the dielectric layer 136 and the stop layer 134. In addition, during the process of forming the opening OP1, the dielectric layer 136 and part of the stop layer 134 in the third region R3 may also be removed to expose a top surface of the electrode 126 and part of a top surface of the isolation structure 102. For example, part of the dielectric layer 136, part of the stop layer 134, and part of the salicide blocking layer 114 may be removed by lithography and etching processes to form the opening OP1 and expose the top surface of the electrode 126 and part of the top surface of the isolation structure 102.

With reference to FIG. 1D, a dielectric layer 138 is formed on the substrate 100. In some embodiments, the dielectric layer 138 may further be formed on the dielectric layer 136 and in the opening OP1. In some embodiments, the dielectric layer 138 may further be formed on the electrode 126 and the isolation structure 102. In addition, the dielectric layer 138 may have a recess R. The material of the dielectric layer 138 is silicon oxide, for example. The dielectric layer 138 is formed by chemical vapor deposition, for example.

Next, a conductive material layer 140 may be formed on the dielectric layer 138. In some embodiments, the conductive material layer 140 may be formed in the recess R. The material of the conductive material layer 140 is a metal compound, a doped semiconductor, or a metal, for example. The metal compound is titanium nitride (TiN), tantalum nitride (TaN), or a metal silicide (e.g., cobalt silicide or nickel silicide), for example. The doped semiconductor is doped polysilicon, for example. The metal is ruthenium (Ru), for example. The conductive material layer 140 is formed by chemical vapor deposition or physical vapor deposition, for example.

Then, a hard mask material layer 142 may be formed on the conductive material layer 140. In some embodiments, the hard mask material layer 142 may be formed in the recess R. The material of the hard mask material layer 142 is silicon nitride, silicon oxynitride, silicon carbonitride, or silicon oxycarbonitride, for example. The hard mask material layer 142 is formed by chemical vapor deposition, for example.

With reference to FIG. 1E, the hard mask material layer 142 and the conductive material layer 140 may be patterned to form a hard mask layer 142a and a gate 140a. Accordingly, the gate 140amay be formed on the dielectric layer 138. The hard mask layer 142a and the gate 140a may be located in the first region R1. A bottom surface of the gate 140a and a bottom surface of the gate 106 are located on different planes. In some embodiments, the bottom surface of the gate 140a may be higher than the bottom surface of the gate 106. The hard mask layer 142a is located on the gate 140a. The hard mask layer 142a and the gate 140a may be located in the recess R. In some embodiments, patterning the conductive material layer 140 may further form a conductive spacer 140b on a sidewall of the recess R. The conductive spacer 140b may be located in the first region R1. In some embodiments, patterning the hard mask material layer 142 and the conductive material layer 140 may further form a hard mask layer 142b and an electrode 140c. The hard mask layer 142b and the electrode 140c may be located in the third region R3. The electrode 140c is located on the dielectric layer 138. The hard mask layer 142b is located on the electrode 140c. In some embodiments, patterning the conductive material layer 140 may further form a conductive spacer 140d on a sidewall of the dielectric layer 138. The conductive spacer 140d may be located in the third region R3. In some embodiments, the hard mask material layer 142 and the conductive material layer 140 may be patterned by lithography and etching processes.

Then, a dielectric layer 144 may be formed on the dielectric layer 138. The material of the dielectric layer 144 is silicon oxide, for example. The dielectric layer 144 is formed by chemical vapor deposition, for example. Next, a planarization process may be performed on the dielectric layer 144. The planarization process is a chemical mechanical polishing process, for example.

Next, interconnect structures (not shown) may be formed during the subsequent manufacturing processes depending on requirements, of which the description is omitted here.

In addition, the semiconductor structure 10, a semiconductor structure 20, and a semiconductor structure 30 may be formed by the method described above. In some embodiments, the semiconductor structure 30 may be a capacitor structure. The semiconductor structure 30 may include the electrode 126, the dielectric layer 138, and the electrode 140c. The electrode 126 is located on the isolation structure 102. The dielectric layer 138 is located on the electrode 126. The electrode 140c is located on the dielectric layer 138.

The semiconductor structure 20 of this embodiment with FIG. 1E will be described below. In addition, although forming the semiconductor structure 20 is described using the method described above as an example, the disclosure is not limited thereto.

With reference to FIG. 1E, the semiconductor structure 20 includes the substrate 100, the dielectric layer 104, the gate 106, the dielectric layer 138, and the gate 140a. The semiconductor structure 20 may be located in the first region R1. In some embodiments, the semiconductor structure 20 may be a transistor structure, for example, a high voltage transistor structure. In some embodiments, the semiconductor structure 20 may be a laterally diffused metal oxide semiconductor (LDMOS) transistor structure. The dielectric layer 104 is located on the substrate 100. The gate 106 is located on the dielectric layer 104. The dielectric layer 138 is located on the substrate 100. The dielectric layer 138 may further be located on the gate 106. The dielectric layer 138 and the dielectric layer 104 may be separated from each other. The dielectric layer 138 may have the recess R. The gate 140a is located on the dielectric layer 138. The bottom surface of the gate 140a and the bottom surface of the gate 106 are located on different planes. In some embodiments, the bottom surface of the gate 140a may be higher than the bottom surface of the gate 106. The gate 140a may be located in the recess R.

In some embodiments, the semiconductor structure 20 may further include the conductive spacer 140b. The conductive spacer 140b is located on the sidewall of the recess R. The conductive spacer 140b and the gate 140a may be separated from each other. In some embodiments, the semiconductor structure 20 may further include the hard mask layer 142a. The hard mask layer 142a is located on the gate 140a. In some embodiments, a width of the hard mask layer 142a may be equal to a width of the gate 140a.

In some embodiments, the semiconductor structure 20 may further include the stop layer 134. The stop layer 134 is located on the gate 106. The stop layer 134 may be in direct contact with the top surface of the gate 106. The stop layer 134 may be located between the dielectric layer 138 and the gate 106. The stop layer 134 may be not located directly below the gate 140a. In some embodiments, the semiconductor structure 20 may further include the dielectric layer 136. The dielectric layer 136 may be located between the dielectric layer 138 and the stop layer 134.

In addition, reference may be made to the description of the embodiments above for the remaining members in the semiconductor structure 20. Moreover, the materials, arrangement, formation, and effects of the members in the semiconductor structure 20 have been described in detail in the embodiments above, and will not be described here again.

As can be known based on the embodiments above, in the semiconductor structure 20 and the manufacturing method thereof, since the semiconductor structure 20 includes the gate 106 and the gate 140a, and the bottom surface of the gate 140a and the bottom surface of the gate 106 are located on different planes, the on-resistance of the semiconductor structure 20 may be reduced by the gate 140a, accordingly improving the electrical performance of the semiconductor structure 20.

In summary of the foregoing, in the semiconductor structure and the manufacturing method thereof in the embodiments above, the on-resistance of the semiconductor structure may be reduced, accordingly improving the electrical performance of the semiconductor structure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate;
a first dielectric layer located on the substrate;
a first gate located on the first dielectric layer;
a second dielectric layer located on the substrate; and
a second gate located on the second dielectric layer, wherein a bottom surface of the second gate and a bottom surface of the first gate are located on different planes.

2. The semiconductor structure according to claim 1, wherein the bottom surface of the second gate is higher than the bottom surface of the first gate.

3. The semiconductor structure according to claim 1, wherein the second dielectric layer and the first dielectric layer are separated from each other.

4. The semiconductor structure according to claim 1, wherein the second dielectric layer has a recess, and the second gate is located in the recess.

5. The semiconductor structure according to claim 4, further comprising:
a conductive spacer located on a sidewall of the recess.

6. The semiconductor structure according to claim 5, wherein the conductive spacer and the second gate are separated from each other.

7. The semiconductor structure according to claim 1, wherein the second dielectric layer is further located on the first gate.

8. The semiconductor structure according to claim 1, further comprising:
a hard mask layer located on the second gate.

9. The semiconductor structure according to claim 8, wherein a width of the hard mask layer is equal to a width of the second gate.

10. The semiconductor structure according to claim 1, further comprising:
a stop layer located on the first gate.

11. The semiconductor structure according to claim 10, wherein the stop layer is in direct contact with a top surface of the first gate.

12. The semiconductor structure according to claim 10, wherein the stop layer is located between the second dielectric layer and the first gate.

13. The semiconductor structure according to claim 10, wherein the stop layer is not located directly below the second gate.

14. A manufacturing method of a semiconductor structure, comprising:
providing a substrate;
forming a first dielectric layer on the substrate;
forming a first gate on the first dielectric layer;
forming a second dielectric layer on the substrate; and
forming a second gate on the second dielectric layer, wherein a bottom surface of the second gate and a bottom surface of the first gate are located on different planes.

15. The manufacturing method according to claim 14, wherein the bottom surface of the second gate is higher than the bottom surface of the first gate.

16. The manufacturing method according to claim 14, wherein forming the second gate comprises:
forming a conductive material layer on the second dielectric layer;
forming a hard mask material layer on the conductive material layer; and
patterning the hard mask material layer and the conductive material layer to form a hard mask layer and the second gate.

17. The manufacturing method according to claim 16, wherein the second dielectric layer has a recess, and the hard mask layer and the second gate are located in the recess.

18. The manufacturing method according to claim 17, wherein patterning the conductive material layer further comprises forming a conductive spacer on a sidewall of the recess.

19. The manufacturing method according to claim 14, further comprising:
forming a stop layer on the first gate before forming the second dielectric layer;
forming a third dielectric layer on the stop layer; and
forming an opening in the third dielectric layer and the stop layer, wherein the second dielectric layer is further formed on the third dielectric layer and in the opening.

20. The manufacturing method according to claim 19, further comprising:
performing a planarization process on the third dielectric layer before forming the opening.
